(19) United States
(12) Patent Application Publication
(10) Pub. No.: US 2026/0216758 A1
(43) Pub. Date: Jul. 30, 2026

(54) METHOD FOR CLEANING A MASK INSPECTION DEVICE, MASK INSPECTION SYSTEM, AND CLEANING STATION

(71) Applicant: Carl Zeiss SMT GmbH, Oberkochen (DE)

(72) Inventor: Tobias Hegele, Aalen (DE)

(21) Appl. No.: 19/460,490

(22) Filed: Jan. 27, 2026

(30) Foreign Application Priority Data
Jan. 27, 2025 (DE) 102025102838.9

(51) Int. Cl. B08B 5/02; G01N 21/956; G02B 27/00; G03F 1/84; G03F 7/00

(52) U.S. Cl. CPC B08B 5/02; G01N 21/956; G02B 27/0006; G03F 1/84; G03F 7/7085; G01N 2021/95676; G01N 2201/0636

(57) ABSTRACT

A method for cleaning a mask inspection device, the mask inspection device comprising a housing and a plurality of EUV mirrors located in the housing. The method involves inserting a cleaning gas generator into an interior space of the housing. The cleaning gas generator produces a cleaning gas jet, the cleaning gas jet being oriented such that the cleaning gas jet strikes an optical surface of an EUV mirror of the mask inspection device. The cleaning gas generator is taken out of the interior space of the housing. The invention also relates to a mask inspection system and to a cleaning station.

### CROSS-REFERENCE TO RELATED APPLICATION

This application claims benefit under 35 U.S.C. §119 to German Patent Application 102025102 838.9, filed on January 27, 2025, the entire content of which is incorporated herein by reference.

### TECHNICAL FIELD

The invention relates to a method for cleaning a mask inspection device, to a mask inspection system and to a cleaning station.

### BACKGROUND

Photomasks are used in microlithographic projection exposure apparatuses used to produce integrated circuits with particularly small structures. The photomask illuminated by very short-wave extreme ultraviolet radiation (EUV radiation) is imaged onto a lithography object in order to transfer the mask structure to the lithography object.

To ensure a high quality of the imaging generated on the lithography object, it is necessary for the photomask to be true to size and not adversely affected by contaminations. It is known practice to subject photomasks to an inspection, either prior to the operation in a microlithographic projection exposure apparatus or during a break in operation. To this end, what is known as an aerial image of a portion of the photomask is created, the photomask in the process being imaged not on a lithography object but on an image sensor of an EUV camera. Using the imaging onto the image sensor as a basis, it is possible to make an assessment as to whether the photomask is without defects and contaminations.

The mask inspection device can comprise an illumination system and a projection lens. The illumination system directs EUV radiation, which is emitted by an EUV radiation source, onto the photomask, so that the photomask is illuminated with substantially uniform brightness. The projection lens defines an imaging beam path between the photomask and the image sensor, the imaging beam path extending via a plurality of EUV mirrors. The illumination system and the projection lens are located in a mask inspection device housing, in which a vacuum is applied during operation of the mask inspection device. Both the illumination system and the projection lens comprise EUV mirrors at which the EUV radiation is reflected.

### SUMMARY

During operation of the mask inspection device, carbon compounds are deposited on the surfaces of the EUV mirrors and over time these compounds form a carbon layer. This can adversely affect the reflectivity of the EUV mirrors. Such a carbon layer can be removed again by directing a jet of a cleaning gas onto the carbon layer. The cleaning gas reacts with the carbon layer and removes it from the coated surface. A good cleaning effect is produced, for example, when the cleaning gas contains a high proportion of hydrogen radicals.

WO 2009/059614 A1 and DE 102010044970 A1 disclose microlithographic projection exposure apparatuses equipped with a fixedly integrated generator for discharging a cleaning gas. The entire contents of WO 2009/059614 and DE 10 2010 044970 are incorporated by reference. Such an integrated generator is associated with some equipment outlay, which can be justified if the carbon layer builds up quickly during operation of the projection exposure system and therefore cleaning is required at short intervals. However, it has been shown that, because of outgassing, the components of the generator can themselves contribute to the build-up of carbon layers. A component that is supposed to assist the functional capability of the projection exposure apparatus accordingly has the side effect of shortening the duration for which it can operate without maintenance.

The problem addressed by the invention is that of presenting a method for cleaning a mask inspection device, a mask inspection system and a cleaning station which alleviate these disadvantages. The aspect is achieved by the features of the independent claims. Advantageous embodiments are specified in the dependent claims.

In a method according to the invention for cleaning a mask inspection device, the mask inspection device comprises a housing and a plurality of EUV mirrors located in the housing. A cleaning gas generator is inserted into an interior space of the housing. The cleaning gas generator produces a cleaning gas jet, the cleaning gas jet being oriented such that the cleaning gas jet strikes an optical surface of an EUV mirror of the mask inspection device. The cleaning gas generator is taken out of the interior space of the mask inspection device.

The invention proposes dispensing with a cleaning gas generator that is integrated in the mask inspection device. The outlay on equipment in the mask inspection device can be reduced in this way and at the same time one of the sources of carbon contaminants can be avoided. The mask inspection device becomes more compact and less complex, this having a positive effect on its susceptibility to errors. Only when cleaning is required is a cleaning gas generator inserted into the interior space of the mask inspection device. The cleaning gas jet discharged by the cleaning gas generator is directed onto the optical surface of an EUV mirror until the carbon layer has been sufficiently removed. After the cleaning process has finished, the cleaning gas generator is taken back out and normal operation of the mask inspection device can be resumed.

The housing of the mask inspection device can be vacuum-tight. During operation of the mask inspection device, in the interior space of the housing it is possible to apply a vacuum, for example, between 10⁻³ mbar and 10⁻⁹ mbar, preferably between 10⁻⁶ mbar and 10⁻⁹ mbar. The mask inspection device can comprise a vacuum pump designed to apply such a pressure in the interior space of the housing.

The mask inspection device can comprise a projection lens which is designed to form an imaging beam path by means of which a structure formed on the surface of a photomask is imaged onto the image sensor. The projection lens can comprise one or more EUV mirrors at which the EUV radiation of the imaging beam path is reflected during operation of the mask inspection device. The method according to the invention allows one or more of the EUV mirrors of the projection lens to be cleaned.

The mask inspection device can comprise an illumination system used to direct EUV radiation, which is emitted by an EUV radiation source, onto the photomask, so that the photomask is illuminated with substantially uniform brightness. The illumination system can comprise one or more EUV mirrors, at which the EUV radiation between the EUV radiation source and the photomask is reflected. The method according to the invention allows one or more of the EUV mirrors of the illumination system to be cleaned.

The housing of the mask inspection device can be provided with a housing opening which is closed by a closure device during operation of the mask inspection device. The closure device makes it possible to apply the pressure difference between the interior space of the housing and the exterior space. Atmospheric pressure may be present in the exterior space.

For the cleaning process, the closure device can be opened so that the interior space of the housing can be accessed through the housing opening. The cleaning gas generator can be inserted into the interior space of the housing through the housing opening. In particular, a cleaning head of the cleaning gas generator can be inserted into the interior space in this way.

The cleaning gas generator can be a stand-alone device not limited to use with a single mask inspection device. This opens up the possibility of using a single cleaning gas generator for the cleaning of different mask inspection devices. The cleaning gas generator can comprise a cleaning head from which the cleaning gas jet emerges when the cleaning gas generator is operating. When the cleaning gas generator has been inserted into the interior space of the mask inspection device, the cleaning head can be located in the interior space, so that the cleaning gas jet emerges in the interior space of the housing. The interior space refers to the space that lies inside the housing when the housing opening is closed by the closure device. It is not necessary for the cleaning gas generator as a whole to be inserted into the interior space of the mask inspection device. The cleaning gas generator can comprise components that are located outside the interior space during the cleaning process. These components can include, for example, connections or a reservoir from which hydrogen is supplied.

The cleaning gas generator can be connected to the housing of the mask inspection device during the cleaning process. The cleaning gas generator can terminate vacuum-tightly with the housing, so that it is possible to apply a vacuum in the interior space of the housing that corresponds to the vacuum during operation of the mask inspection device. The cleaning gas generator can have a flange that matches a flange surrounding the housing opening.

The closure device can be a housing cover which closes the housing opening during operation of the mask inspection device. The housing cover can be designed such that it can be taken off of the housing on its own, i.e., without taking off further components at the same time, in order to open up the housing opening. The housing opening can be an inspection opening.

Alternatively, the closure device can bear a component of the mask inspection device, so that the component is attached to the housing via the closure device. In one embodiment, the component borne by the closure device is an EUV camera, onto the image sensor of which the photomask is imaged by use of the projection lens of the mask inspection device. In that case, the closure device bears the image sensor. When the closure device is opened, the image sensor is also taken off of the housing of the mask inspection device. The closure device can be designed such that, during operation of the mask inspection device, the image sensor is exposed to the vacuum in the interior space of the housing and such that a housing of the camera adjoins the exterior space.

In addition or alternatively, the closure device can bear an EUV mirror. When the closure device is opened, the EUV mirror is also taken off of the housing of the mask inspection device in this case. The closure device can bear a plurality of components of the mask inspection device, for example, a mirror module and the EUV camera, two or more mirror modules, a mirror module or the EUV camera and a further component of the mask inspection device.

The cleaning gas jet can comprise hydrogen radicals. The designation “hydrogen radicals” serves here as a generic term for ionic hydrogen species and hydrogen species in an excited electron state. They can be atomic hydrogen species, as can be produced by splitting H₂ molecules. The hydrogen radicals can make up a proportion of at least 10%, preferably at least 20%, more preferably at least 50% of the particles in the gas jet discharged by the cleaning gas generator.

The cleaning gas generator can comprise a reservoir of gaseous hydrogen or be connected to such a reservoir. The cleaning gas generator can comprise an activation unit designed to act on molecular hydrogen in order to produce hydrogen radicals. The activation unit can comprise an electron source. Electrons discharged from the electron source can be accelerated under the influence of an electric field. The molecular hydrogen can be directed into the region of the activation unit, causing collisions between the electrons and the hydrogen molecules. Depending on the kinetic energy of the electrons, different types of hydrogen radicals are generated.

The electron source can comprise a filament through which electric current flows. The current intensity can be dimensioned such that electrons are discharged from the filament. The activation unit can comprise an electrode to which is applied an electric potential under which the electrons are accelerated from the filament in the direction of the electrode. The hydrogen molecules can be conducted through the space between the filament and the electrode.

There can be a pressure gradient between the source of the cleaning gas and the object that is to be cleaned by the cleaning gas jet. The cleaning gas jet can be propelled by the pressure gradient. A vacuum can be applied inside the housing of the mask inspection device when the cleaning gas generator is operating. The pressure gradient can be in relation to the source of the hydrogen gas.

The cleaning gas generator can comprise an outlet opening from which the cleaning gas jet emerges. The outlet opening can be located on the cleaning head of the cleaning gas generator. The position of the outlet opening can be adjustable in order to be able to set the direction in which the cleaning gas jet emerges from the cleaning gas generator. In addition or alternatively, the cleaning gas generator can comprise a reflector at which particles of the cleaning gas jet are reflected, so that the direction of the cleaning gas jet is changed. The orientation of the reflector can be adjustable so that the cleaning gas jet can be deflected in different directions. If there are ionic species within the cleaning gas jet, the direction of the cleaning gas jet can also be influenced by electric fields. An embodiment in which the direction of the cleaning gas jet can be changed in this way or in another way without any mechanically moving parts is advantageous because the risk of contamination by particles is reduced.

The method can be carried out such that the cleaning gas generator is connected to the housing of the mask inspection device when the cleaning gas generator has been inserted into the interior space of the housing. The connection can be established such that the opening through which the cleaning gas generator was inserted is vacuum-tightly closed. A vacuum can be applied in the interior space of the housing. The cleaning gas generator can be put into operation such that the cleaning gas jet is directed onto the optical surface of an EUV mirror. The cleaning gas jet can be sustained until enough of a deposited carbon layer on the optical surface has been removed. The cleaning gas jet can then be directed onto another EUV mirror until the latter is also freed of its carbon layer to the desired extent. This can be repeated until all EUV mirrors of the mask inspection device that are covered by a carbon layer have been cleaned in this way. The cleaning can also be carried out under an atmosphere of extreme clean dry air (XCDA) or under a nitrogen atmosphere.

The length of time it takes for a carbon layer to form on the optical surface of an EUV mirror during operation of the mask inspection device depends, among other things, on the intensity of the incident EUV radiation. If the intensity is sufficiently high, it is possible to produce enough hydrogen radicals from a hydrogen-containing residual gas composition so that, during operation of the mask inspection device, a carbon layer is not produced at all or the carbon layer is directly broken down again while it is being produced.

Within the EUV beam path between the photomask and the EUV camera, the intensity of the incident EUV radiation depends on the surface area on which the incident EUV radiation is concentrated. Thus, EUV mirrors of small surface area are exposed to a higher intensity of the EUV radiation than EUV mirrors of large surface area. The method can be carried out such that only EUV mirrors of large surface area are cleaned by the method according to the invention, whereas EUV mirrors of small surface area are not cleaned. The EUV mirrors of large surface area can be at least the two largest, preferably at least the three largest EUV mirrors of the mask inspection device. EUV mirrors of small surface area can be at least the smallest EUV mirror, preferably at least the two smallest EUV mirrors.

The method can be carried out such that the cleaning gas generator remains connected to the housing of the mask inspection device while all of the treated EUV mirrors are being cleaned. It is also possible that the cleaning gas generator is detached from the housing after a first EUV mirror has been cleaned. For the cleaning of a second EUV mirror, a cleaning gas generator can be connected to a different housing opening of the mask inspection device. The cleaning gas generator can be the same one as or a different one to that used for cleaning the first EUV mirror. It is also possible that a different cleaning gas generator, or the same cleaning gas generator in a different operating state, is connected to the same housing opening as that used for cleaning the first EUV mirror. This affords the possibility of cleaning multiple EUV mirrors of the mask inspection device in succession, even if this is not possible with the configuration of the cleaning gas generator when the first EUV mirror is being treated.

It is also possible that a portion of the EUV mirrors of the mask inspection device is cleaned by the method according to the invention and that another portion of the EUV mirrors of the mask inspection device is cleaned by an alternative method. An EUV mirror cleaned by an alternative method can be dismounted from the mask inspection device beforehand. Other EUV mirrors of the mask inspection device can be cleaned by the method according to the invention while the EUV mirror provided for the external cleaning is installed in the mask inspection device or dismounted. It is also possible that a portion of the other EUV mirrors in the installed state and a portion with the EUV mirror provided for the external cleaning being dismounted are cleaned by the method according to the invention.

An external cleaning of EUV mirrors of a mask inspection device can be carried out in a cleaning station that can be used as a stand-alone unit independently of a mask inspection device.

The cleaning station can comprise a chamber which is dimensioned such that an EUV mirror to be cleaned can be inserted into the interior space of the chamber. The chamber can comprise an opening that can be closed with a cover. In the closed state, the chamber may be vacuum-tight. The cleaning station can comprise one or more outlet openings from which a cleaning gas jet can be directed onto the optical surface of an EUV mirror located in the chamber. The outlet openings can take the form of outlet nozzles. The cleaning station can comprise a receptacle which bears an EUV mirror located in the chamber. The cleaning station can be further developed with features described in the context of the method according to the invention or in the context of the mask inspection system according to the invention. Such a cleaning station has independently inventive content, even without the fact that the EUV mirrors of a mask inspection device are cleaned in the installed state. The disclosure encompasses developments of the cleaning station with features that are described in the context of the method according to the invention or the mask inspection system according to the invention.

During operation of the mask inspection device, an examination field on the surface of the photomask can be illuminated with EUV radiation. The intensity of the EUV radiation on the examination field can be substantially constant. The image sensor of the EUV camera can be sensitive to electromagnetic radiation in the EUV wavelength range. In the course of operation of the mask inspection device, a carbon layer is deposited on the optical surface of one or more EUV mirrors of the projection lens.

As the carbon layer grows, the reflectivity of an EUV mirror decreases. This has the effect of reducing the intensity of the EUV radiation incident on the image sensor. The operation of the mask inspection device can be interrupted when the intensity of the EUV radiation incident on the image sensor reaches a lower threshold value of normal operation. During an interruption in operation, one or more EUV mirrors of the mask inspection device can be cleaned by the method according to the invention. After the cleaning cycle has finished, the operation of the mask inspection device can resume, so that images of photomasks can be recorded by the image sensor.

The term “EUV radiation” denotes electromagnetic radiation in the extreme ultraviolet spectral range with wavelengths of between 5 nm and 30 nm. In particular, the EUV radiation can have a wavelength of 13.5 nm. The EUV mirrors of the projection lens can have a high reflectivity for electromagnetic radiation of this wavelength.

The invention also relates to a mask inspection system which has a mask inspection device and a cleaning gas generator for producing a cleaning gas jet. The mask inspection device comprises an image sensor, a housing and a plurality of EUV mirrors located in the housing. In a state of use of the mask inspection system, the cleaning gas generator is separated from the mask inspection device and the mask inspection device is configured to use the image sensor to record image data of the photomask. In a cleaning state, a cleaning gas generator is inserted into an interior space of the mask inspection device such that the cleaning gas jet is directed onto an optical surface of an EUV mirror of the mask inspection device.

The mask inspection device can comprise a projection lens and/or an illumination system. The illumination system can be designed to direct EUV radiation emitted by an EUV radiation source onto the photomask by use of a plurality of EUV mirrors. The projection lens can be designed to form, by use of a plurality of EUV mirrors, an imaging beam path by way of which a structure formed on the surface of the photomask is imaged onto the image sensor.

The disclosure encompasses developments of the mask inspection system with features that are described in the context of the method according to the invention. The disclosure encompasses developments of the method which are described in the context of the mask inspection system according to the invention.

### BRIEF DESCRIPTION OF DRAWINGS

The invention is described by way of example below on the basis of advantageous embodiments and with reference to the accompanying drawings, in which:

FIG. 1: shows a schematic illustration of a mask inspection device;

FIGS. 2-5: show a first embodiment of a mask inspection system according to the invention;

FIGS. 6-8: show a second embodiment of a mask inspection system according to the invention;

FIGS. 9-11: show a third embodiment of a mask inspection system according to the invention;

FIG. 12: shows a microlithographic projection exposure apparatus.

### DETAILED DESCRIPTION

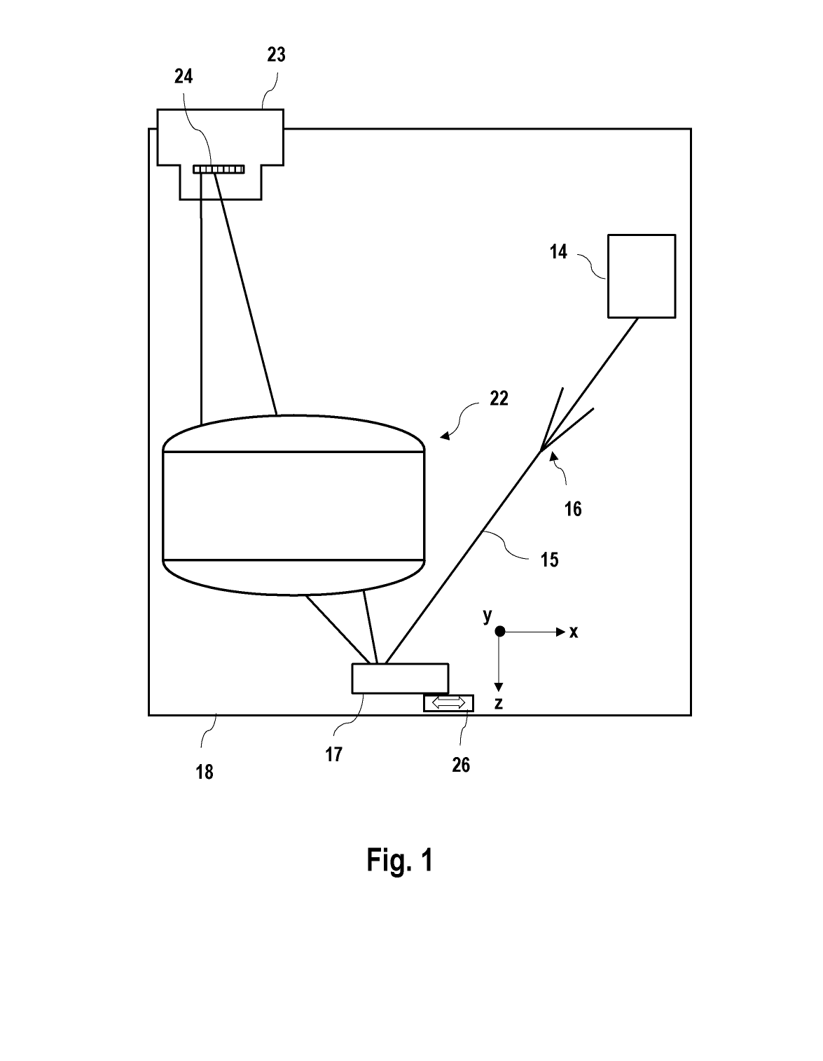

Microlithographic photomasks 17 can be examined by use of a mask inspection apparatus shown in FIG. 1.

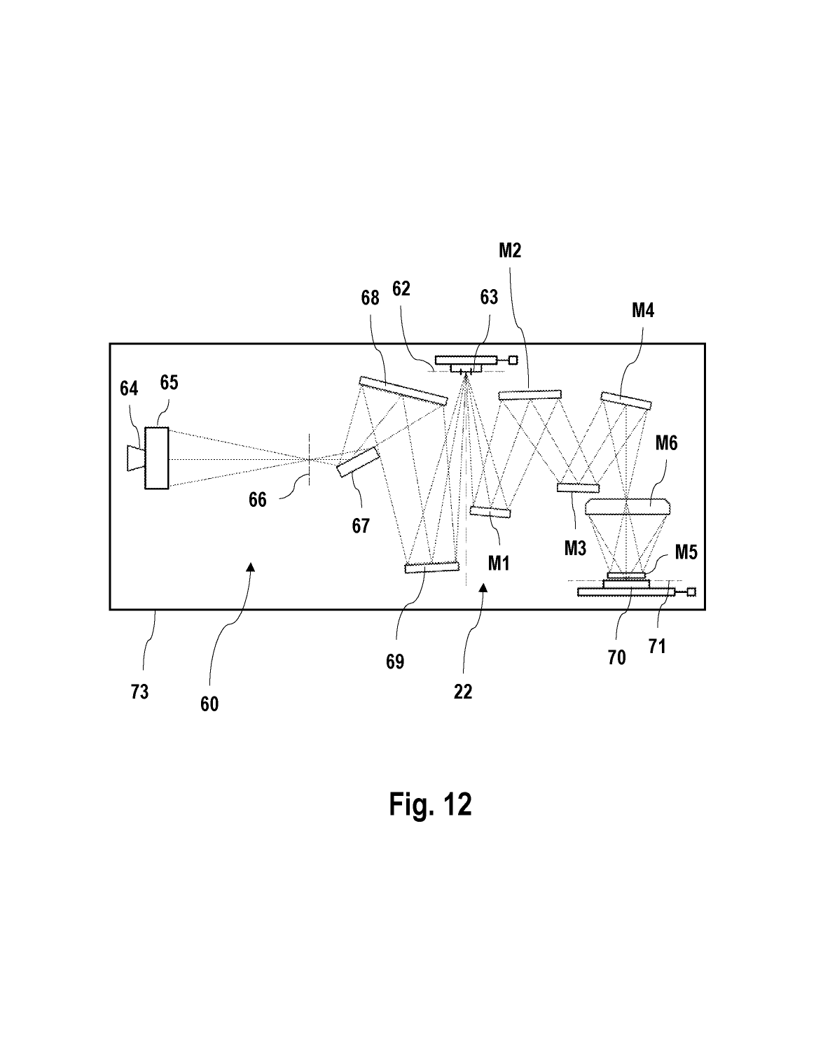

In general, microlithographic photomasks 17 are intended to be used in a microlithographic projection exposure apparatus (see FIG. 12). In the microlithographic projection exposure apparatus, the photomask 17 is illuminated with extreme ultraviolet radiation (EUV radiation) at a wavelength of 5 nm to 30 nm, in particular 13.5 nm, in order to image a structure formed on the photomask 17 onto the surface of a lithographic object in the form of a wafer. The wafer is coated with a photoresist that reacts to the EUV radiation. The mask inspection device is used to examine whether the photomask meets the specifications and is free from contaminations.

According to FIG. 1, the photomask 17 is arranged in the mask inspection device such that an EUV beam path 15 emanating from an EUV radiation source 14 is guided via an illumination system 16 onto the photomask 17. The wavelength of the EUV radiation can match that of the EUV radiation used in the microlithographic projection exposure apparatus. The illumination system 16 is used to shape the EUV radiation to form a beam used to illuminate, with uniform brightness, an examination field on the surface of the photomask 17. The examination field 20 is small in comparison with the surface area of the photomask 17. The illuminated region 20 can have dimensions of 0.5 mm x 0.8 mm, for example. The edge lengths of the photomask 17 may be between 100 mm and 200 mm, for example. A field stop used to delimit the illuminated region to the examination field 20 on the surface of the photomask 17 is arranged in the illumination system 16. Using an XY-positioning mechanism 26, it is possible to move the photomask in the XY-plane in order to bring different examination fields 20 into the region of the EUV beam path.

The EUV beam path 15 reflected off the photomask 17 continues through an EUV projection lens 22 to an EUV camera 23, which is equipped with an image sensor 24. The EUV projection lens is used to image the examination field 20 of the photomask 17 onto the image sensor 24 of the EUV camera 23. The EUV radiation source 14, the illumination system 15, the

photomask 17, the EUV projection lens 22 and the EUV camera 23 are located in a housing 18, in which a negative pressure prevails during operation of the mask inspection device. For example, the image sensor 24 can be a charge coupled device (CCD) sensor or a complementary metal oxide semiconductor (CMOS) sensor. The image sensor 24 can have an array of individually addressable sensing elements or pixels.

The EUV radiation source 14 is, e.g., a plasma radiation source, in which the EUV radiation is emitted from a plasma at a wavelength of 13.5 nm. For example, tin is a medium that can be used to generate a plasma suitable for emitting such EUV radiation. A laser beam can be made to impinge on a droplet of the medium for the purpose of creating the plasma.

For example, the photomask 17 can have an aspect ratio of between 1:1 and 1:3, preferably between 1:1 and 1:2, and particularly preferably of 1:1 or 1:2. The photomask can be substantially rectangular. The photomask may preferably have a length and a width of 5 to 7 inches (12.7 cm to 17.8 cm), particularly preferably a length and a width of 6 inches (15.2 cm). Alternatively, the photomask may have a length of 5 to 7 inches (12.7 cm to 17.8 cm) and a width of 10 to 14 inches (25.4 cm to 35.6 cm), preferably a length of 6 inches (15.2 cm) and a width of 12 inches (30.5 cm).

The EUV projection lens 22 has a magnification factor of, e.g., more than 100. In order to be able to record the entirety of the image generated by the examination field 20 of the photomask 17, the area of the image sensor 24 is greater than the area of the examination field 20 in accordance with the magnification factor.

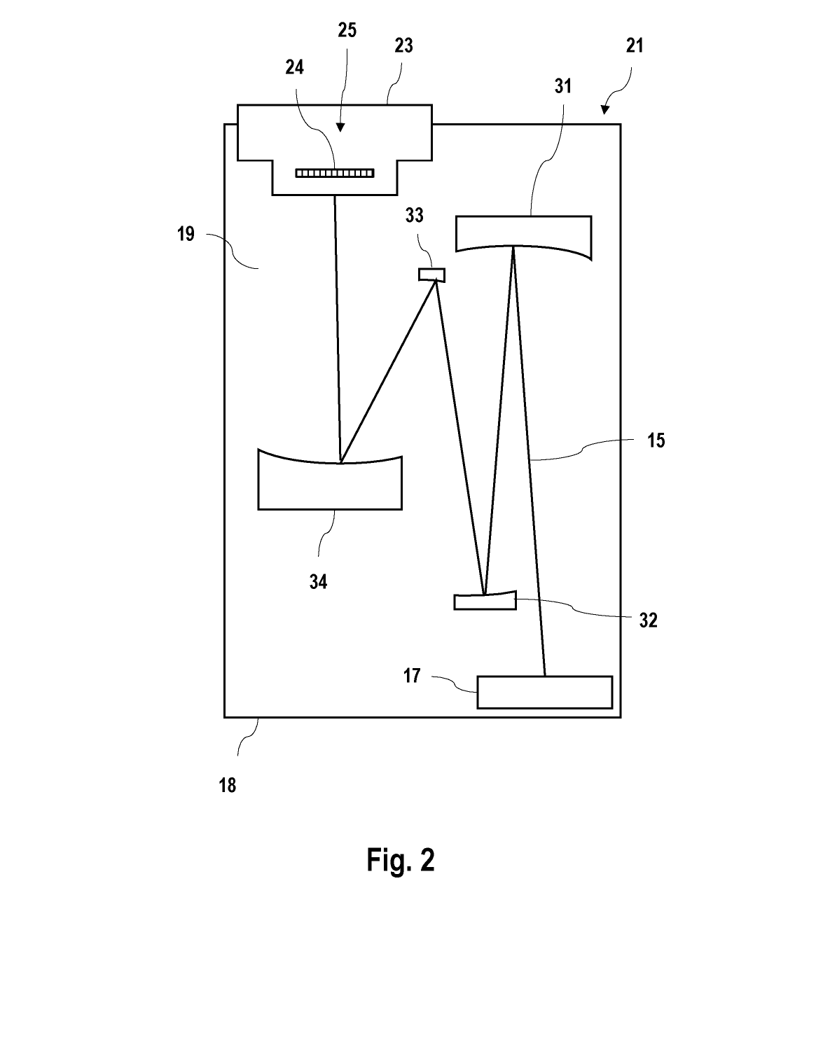

In the schematic illustration of FIG. 2, the EUV projection lens 22 comprises four EUV mirrors 31, 32, 33, 34 used to form the beam path 15 between the photomask 17 and the image sensor 24. The EUV mirrors 31, 32, 33, 34 have a particularly high reflectivity for EUV radiation. The optical surface of the EUV mirrors may be formed by a highly reflective coating. This may be a multilayer coating, in particular a multilayer coating having alternating layers of molybdenum and silicon. Using such a coating, it is possible to reflect approximately 70% of the incident EUV radiation. In FIG. 2, the mask inspection system is shown in the state of use in

which the photomask 17 is imaged onto the image sensor 24 of the EUV camera 23 by use of the EUV beam path 15.

The housing 18, in which a vacuum is applied during operation of the mask inspection device 21, is provided with a housing opening 25. The housing opening 25 is vacuum-tightly closed by the EUV camera 23. The EUV camera 23 has a flange which terminates to match a sealing mating flange of the housing 18. The EUV camera 23 forms a closure device within the meaning of the invention. In this embodiment of the method according to the invention, for carrying out the cleaning process the EUV camera 23 is separated from the housing 18, so that the interior space 19 of the housing 18 can be accessed through the housing opening 25.

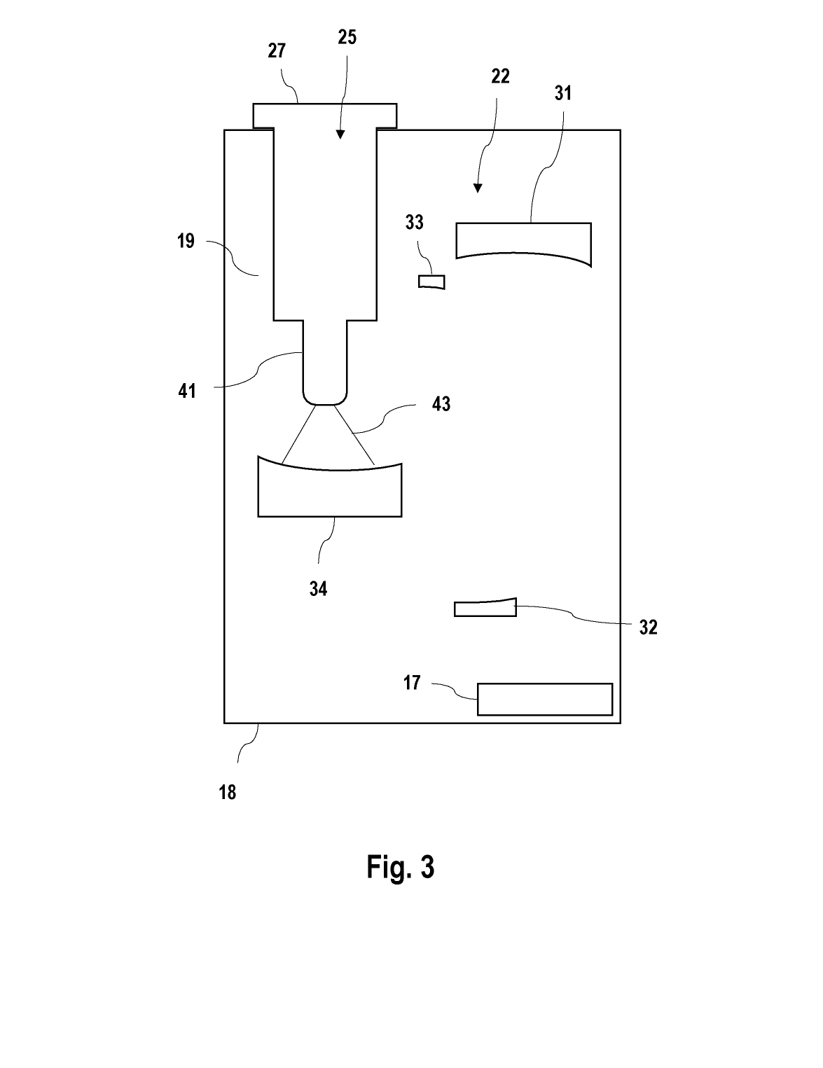

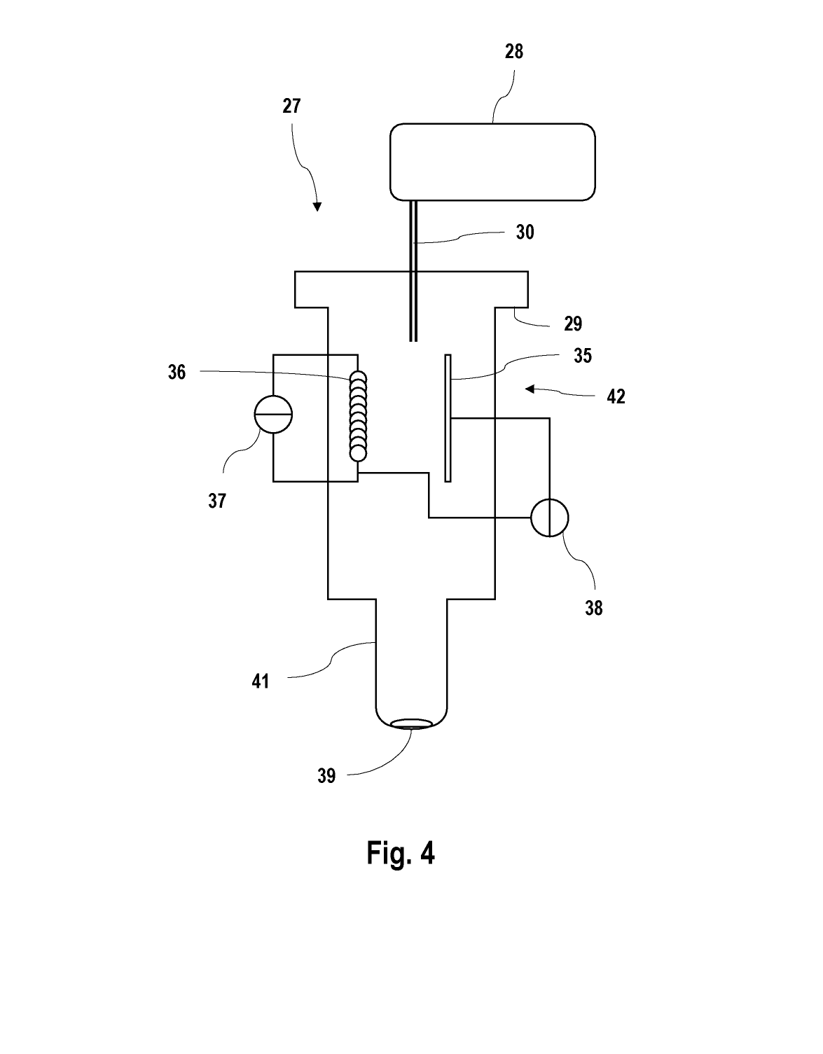

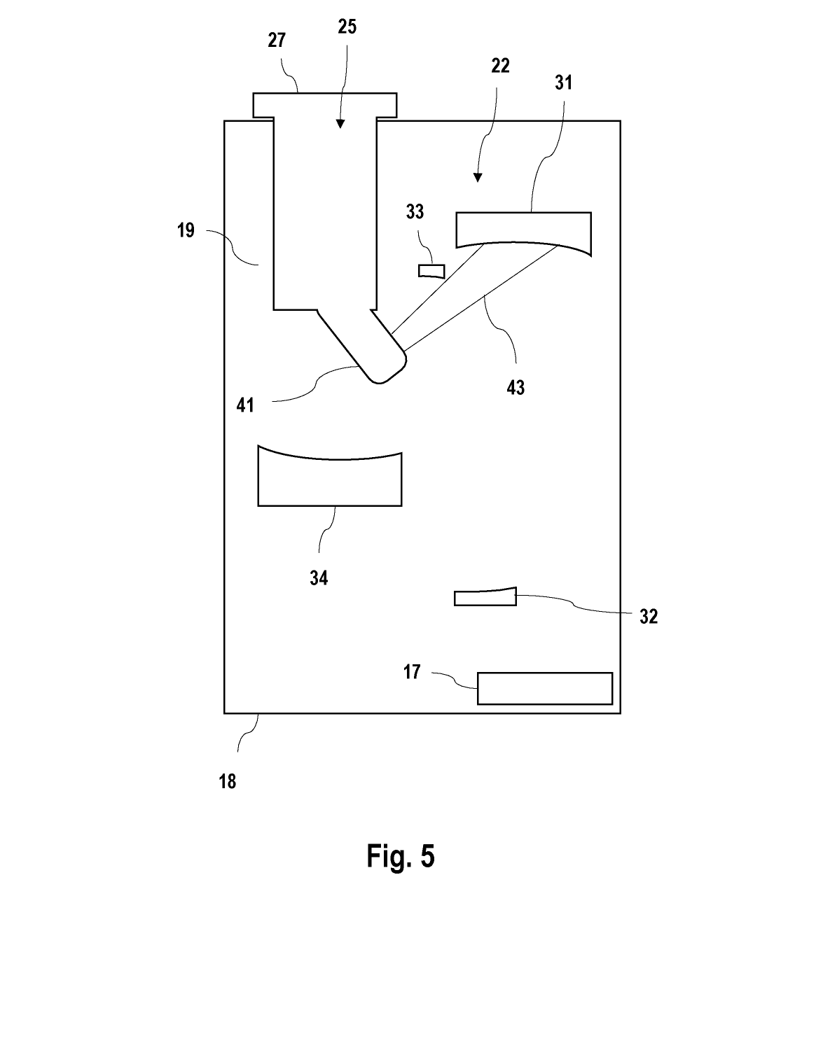

After the EUV camera 23 has been taken off, a cleaning gas generator 27 is connected to the housing opening 25, so that the mask inspection system is in the cleaning state; see FIG. 3. The cleaning gas generator 27 has a flange 29 which corresponds to the flange of the EUV camera 23, thus maintaining the vacuum-tightness of the housing 18.

The cleaning gas generator 27 is connected to a reservoir 28 filled with gaseous hydrogen. A line 30, through which the hydrogen can flow from the reservoir 28 into the cleaning gas generator 27, extends between the interior space of the cleaning gas generator 27 and the reservoir 28. The line 30 can be closed with a valve (not illustrated). The interior space of the cleaning gas generator 27 extends as far as a cleaning head 41 provided with an outlet opening 39. There is a pressure gradient between the reservoir 28 and the outlet opening 39, and so a continuous flow of the hydrogen in the direction of the outlet opening 39 is established.

Between the line 30 and the outlet opening 39, the hydrogen passes through an activation unit 42. In the activation unit, hydrogen radicals are generated from the hydrogen H₂ molecules. The activation unit 42 comprises a filament 36 shaped into coils and connected to a current source 37. The current source 37 is set such that the filament 36 heats up and discharges electrons in large numbers. An electrode 35 is situated opposite the filament 36. A voltage source 38 is used to generate an electric field between the electrode 35 and the filament 36, so that the released electrons are accelerated in the direction of the electrode 35.

A channel through which the hydrogen passes is formed between the electrode 35 and the filament 36. Collisions occur between the hydrogen and the electrons, resulting in hydrogen radicals. The hydrogen radicals emerge from the outlet opening 39 in the form of a cleaning gas jet 43.

According to FIG. 3, the outlet opening 39 is situated opposite the optical surface of the fourth mirror 34 of the mask inspection device 21. The cleaning gas jet 43 strikes the optical surface and removes a carbon layer, which had formed there during operation of the mask inspection device 21. When the cleaning of the fourth mirror 34 has finished, the cleaning gas generator 27 is brought into a different state, in which the cleaning gas jet 43 strikes the optical surface of the first EUV mirror 31. The cleaning gas jet 43 is directed onto the EUV mirror 31 until the latter is also freed of its carbon layer.

This finishes the cleaning of the projection lens 22. The second mirror 32 and the third mirror 33 do not require separate cleaning, because the intensity of the EUV radiation during operation of the mask inspection device 21 is high enough, owing to the substantially smaller surface area, that no carbon layer forms or the carbon layer is directly removed again.

After the cleaning has finished, the mask inspection system can be brought back into the state of use shown in FIG. 2 and normal operation of the mask inspection device 21 can be continued. In the course of operation, carbon layers form on the first mirror 31 and the fourth EUV mirror 34 again, as a result of which the reflectivity of these EUV mirrors drops. Once the amount of EUV light arriving at the EUV camera is small enough that the lower threshold of normal operation is no longer reached, the operation of the mask inspection device 21 is interrupted and a new cleaning cycle is carried out.

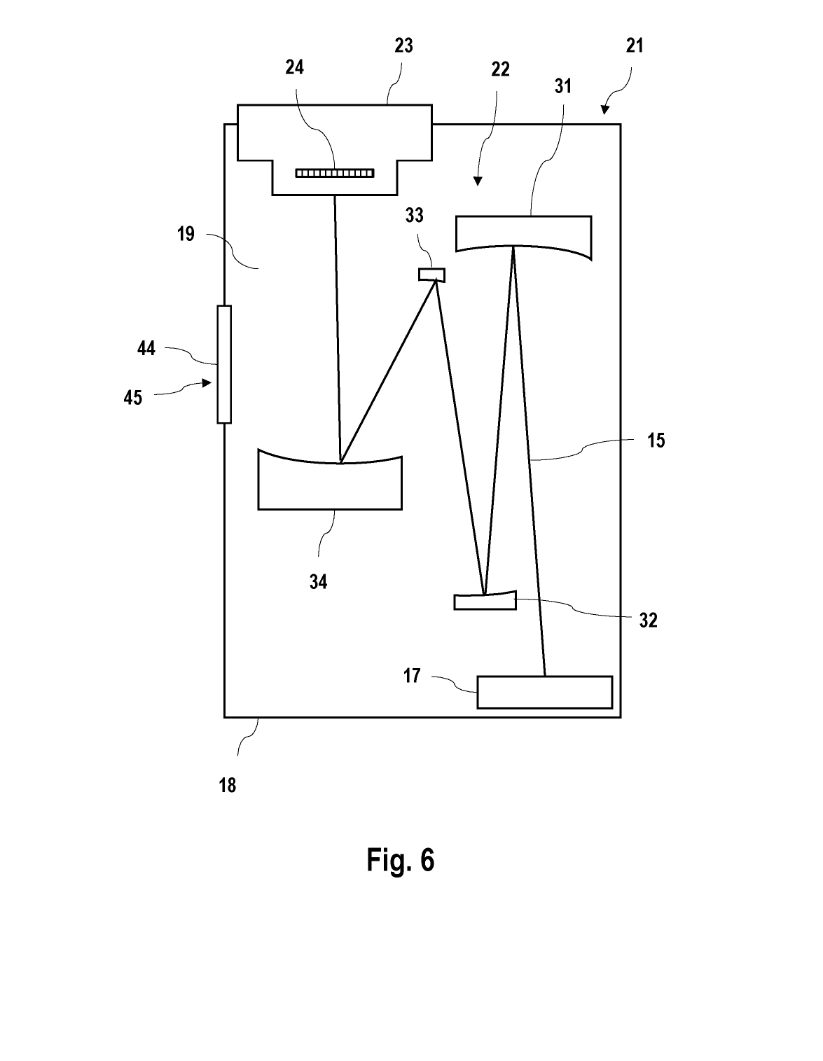

In the case of the mask inspection system according to FIGS. 6-8, the housing 18 has an inspection opening 45 which is vacuum-tightly closed by a closure device in the form of a housing cover 44. When the housing cover 44 is detached from the housing 18, the interior space of the housing 18 can be accessed through the inspection opening 45. This can be used for inspection or maintenance steps.

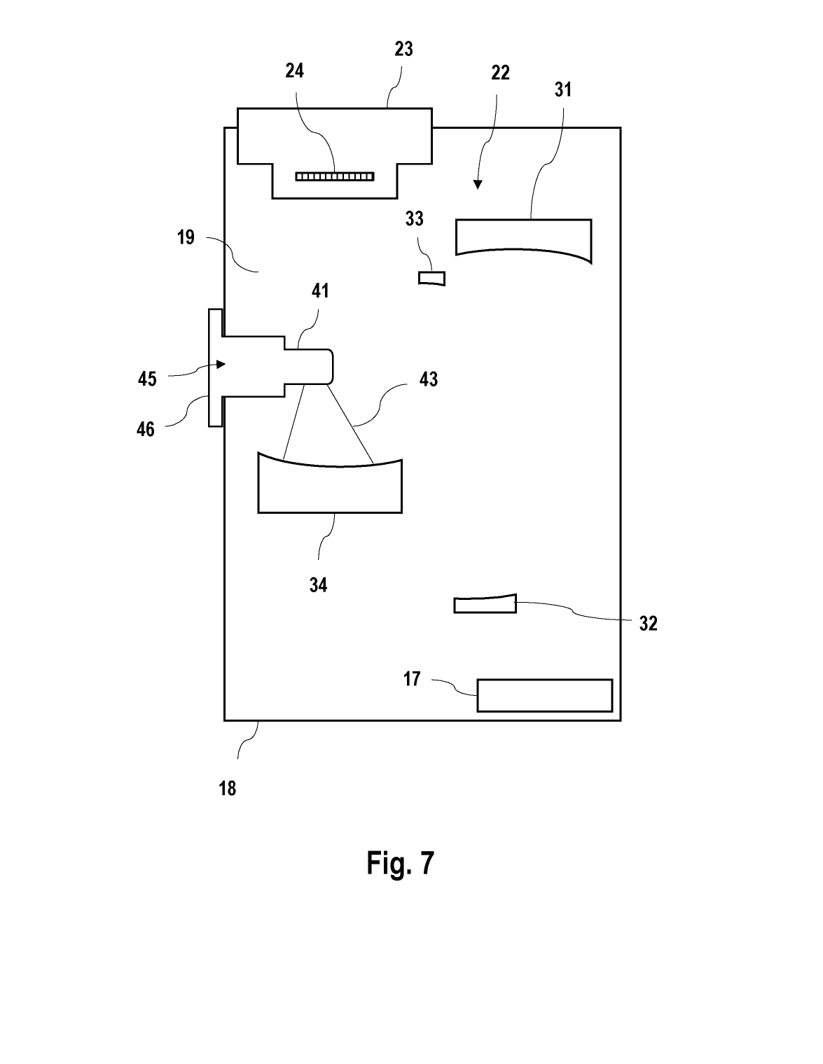

The cleaning gas generator 46 used for this exemplary embodiment has a flange that matches a flange surrounding the inspection opening 45. FIG. 7 shows a state of the inspection system in which the housing cover 44 has been taken off and the cleaning gas generator 46 has been connected to the housing 18 instead. The cleaning gas generator 46, together with the housing 18, forms a seal so that a vacuum can be applied in the interior space of the housing 18. An outlet opening formed on the cleaning head 41 of the cleaning gas generator 46 is oriented such that the emerging cleaning gas jet 43 strikes the optical surface of the fourth EUV mirror 34.

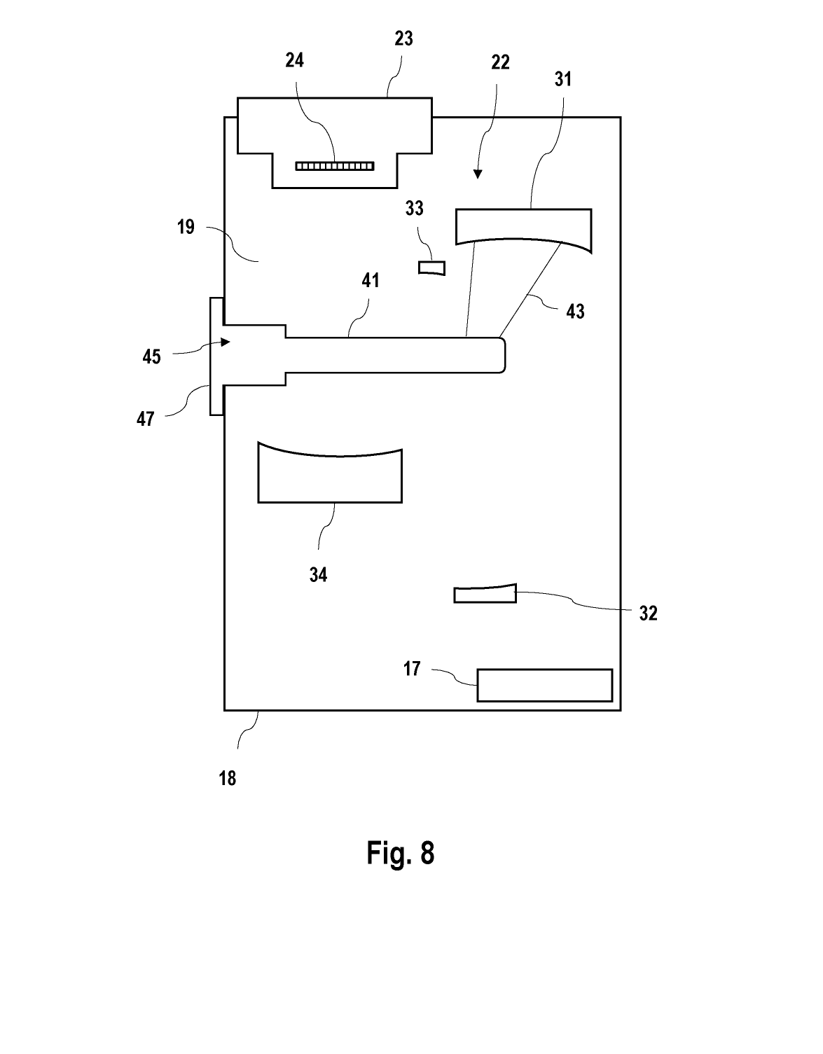

After the fourth EUV mirror 34 has finished being cleaned, the cleaning gas generator 46 is detached from the housing 18 and replaced by an alternative cleaning gas generator 47; see FIG. 8. The alternative cleaning gas generator 47 has a cleaning head 41, of which the outlet opening is directed towards the first EUV mirror 31. The cleaning gas jet 43 is directed onto the optical surface of the first EUV mirror 31 until the carbon layer has been sufficiently removed. Subsequently, the mask inspection system can be put back into the state of use according to FIG. 6 and used for the inspection of photomasks 17. If the intensity of the EUV radiation coming from the EUV camera 23 falls below a lower threshold value of the permissible operating range over time, it can be concluded that carbon layers have been deposited on the first EUV mirror 31 and the fourth EUV mirror 34 again. A new cleaning cycle can then be carried out.

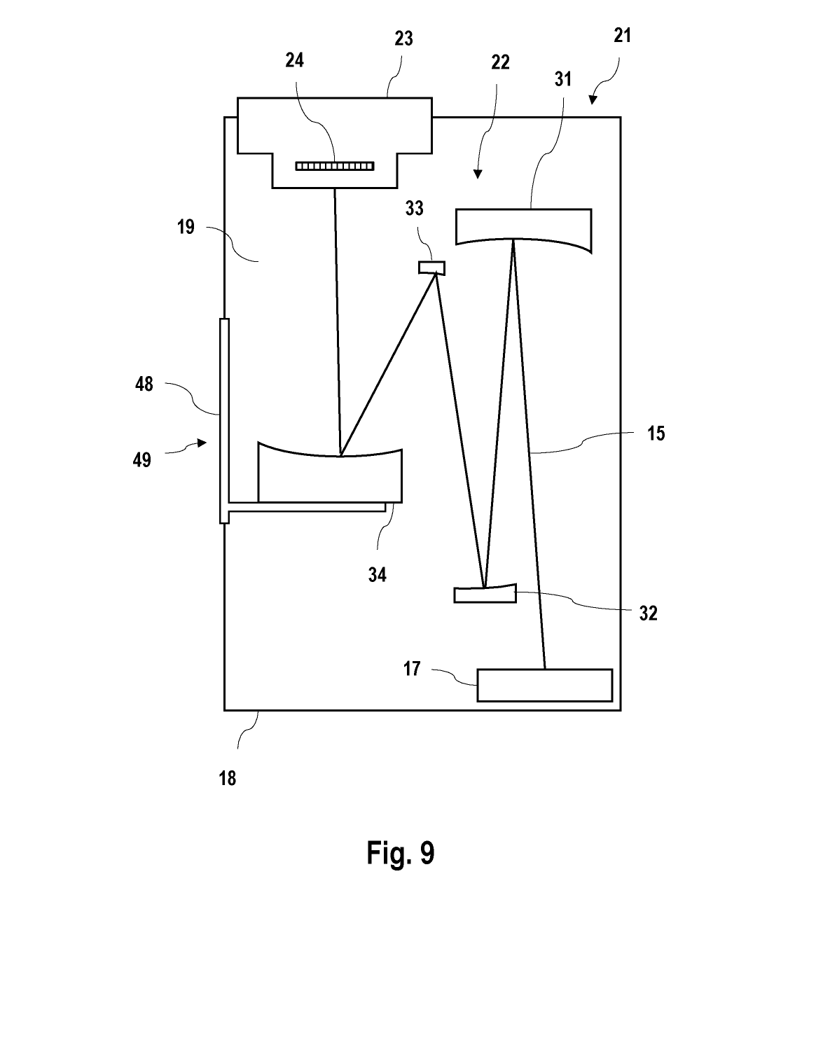

In the exemplary embodiment according to FIGS. 9-12, the mask inspection system comprises a module structural part 48, which bears the fourth EUV mirror 34. The module structural part 48 is connected to a housing opening 49 and forms a sealing termination with a flange surrounding the housing opening 49, so that a vacuum can be applied in the interior space of the housing 18. The module structural part 48 forms a closure device within the meaning of the invention.

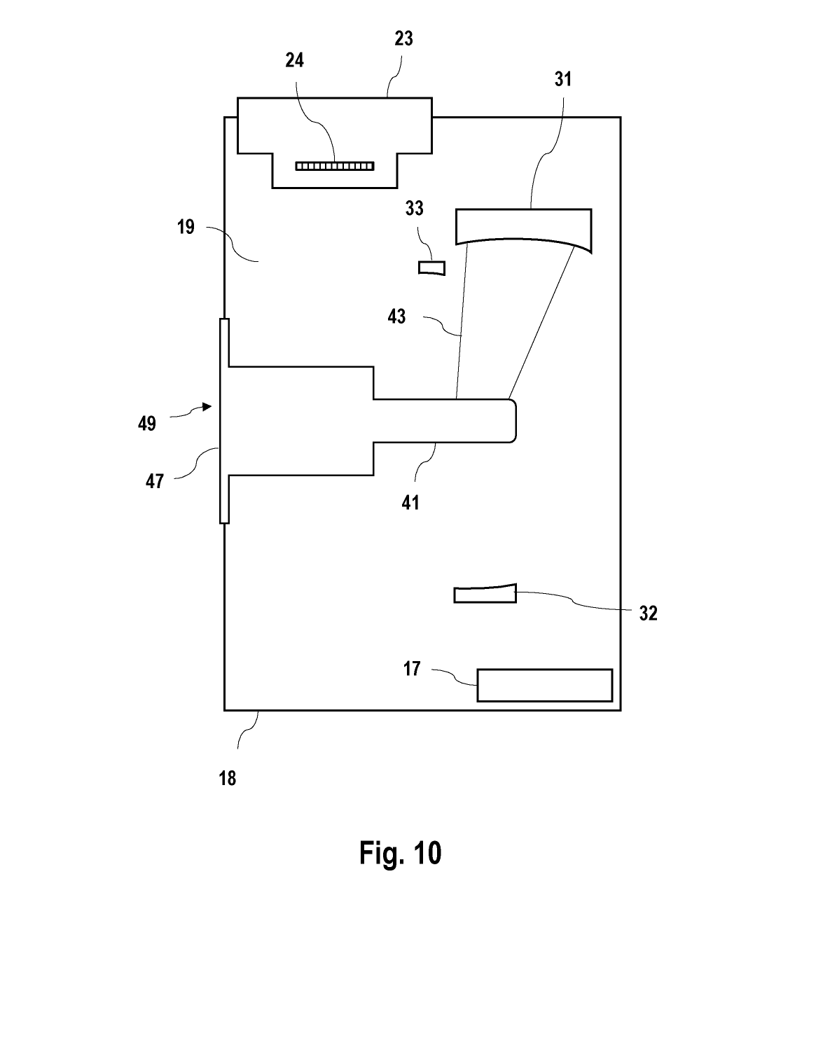

When the module structural part 48 is detached from the housing 18, at the same time the fourth EUV mirror 34 is taken out of the interior space of the housing 18. This creates a free space which can be used for the insertion of a cleaning gas generator 47; see FIG. 10. The cleaning gas generator 47 is configured such that the cleaning gas jet 43 strikes the optical surface of the first EUV mirror 31.

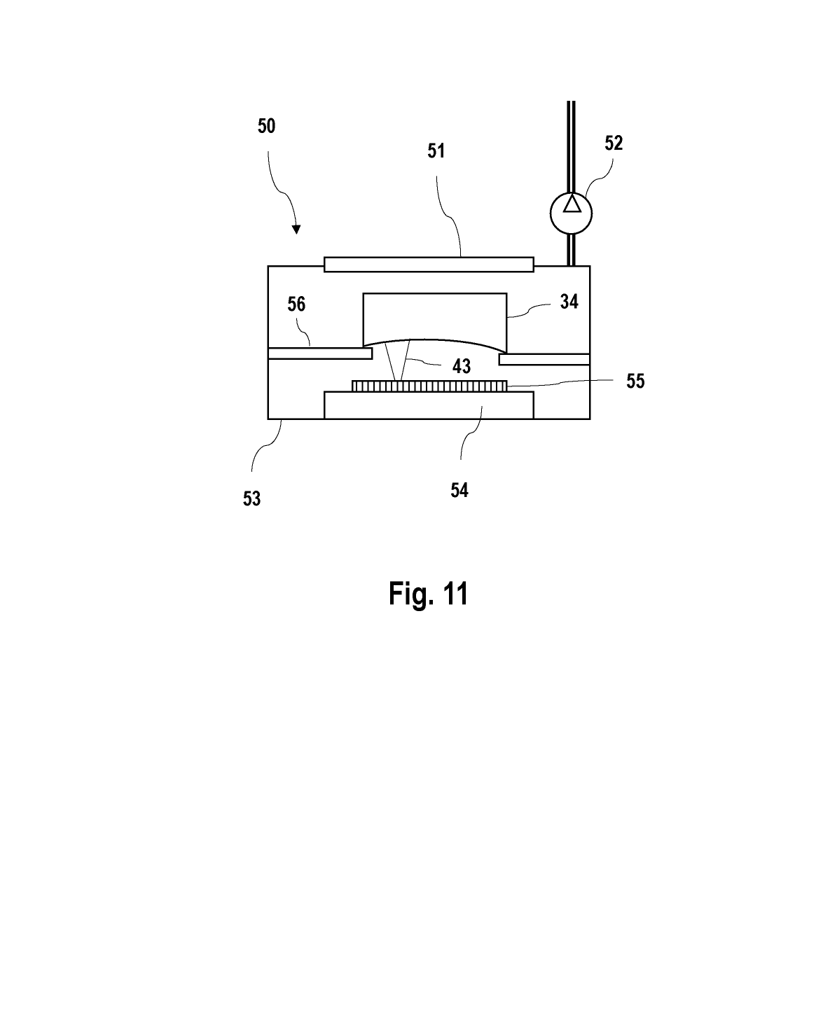

The cleaning process for the fourth EUV mirror 34 is carried out in a separate cleaning station 50; see FIG. 11. The cleaning station 50 comprises a chamber 53, in the interior space of which a vacuum can be applied by a vacuum pump 52. The chamber 53 has an opening which is closed by a cover 51. The opening is dimensioned such that, after taking off the cover 51, the fourth EUV mirror 34 can be inserted into the interior space of the chamber 53. Formed in the interior space is a holding device 56, on which the fourth EUV mirror 34 can be put down in such a way that the optical surface faces downwards. The cleaning station 50 comprises a generator module 54 (only schematically illustrated) used to produce a stream of hydrogen radicals. The generator module 54 comprises a multiplicity of outlet openings 55. A cleaning gas jet 43 emerges from each of the outlet openings 55, this being indicated by way of example from one of the outlet openings 55 in FIG. 11. The optical surface is treated with hydrogen radicals until enough of a carbon layer deposited there has been removed.

Subsequently, the fourth EUV mirror 34 can be re-connected to the housing 18 of the mask inspection device 21 by use of the module structural part 48, in order to bring the mask inspection system back into the state of use according to FIG. 9.

FIG. 12 schematically illustrates a microlithographic EUV projection exposure apparatus. The projection exposure apparatus comprises an exposure beam source 64, an illumination system 60 and a projection lens 22, which are operated jointly in a process chamber 73.

The exposure beam source 64 generates electromagnetic radiation in the EUV range, i.e., at a wavelength of between 5 nm and 30 nm in particular. The exposure radiation emanating from the exposure beam source 64 is focused into an intermediate focal plane 66 by way of a collector 65. Exposure radiation passing across the intermediate focal plane 66 is guided into an object plane 62 by the illumination system 60, with the result that an object field in the object plane 62 is illuminated with uniform radiation intensity.

The illumination system 60 comprises a deflection mirror 67 used to deflect the exposure radiation to a first facet mirror 68. A second facet mirror 69 is disposed downstream of the first facet mirror 68. The second facet mirror 69 is used to image the facets of the first facet mirror 68

into the object plane 62. A photomask 63 is arranged in the object plane 62, and is imaged into an image plane 71 by way of a plurality of mirrors M1-M6 of the projection lens 22. A structure formed on the photomask 63 is transferred to a radiation-sensitive layer of a wafer 70 arranged in the image plane 71.

A number of embodiments of the invention have been described. Nevertheless, it will be understood that various modifications may be made without departing from the spirit and scope of the invention. Furthermore, while some embodiments, examples or aspects described herein include some but not other features included in other embodiments, examples or aspects combinations of features of different embodiments, examples or aspects are meant to be within the scope of the claims, and form different embodiments, as would be understood by those skilled in the art.

What is claimed is:

1. A method for cleaning a mask inspection device, the mask inspection device comprising a housing and a plurality of EUV mirrors located in the housing, the method comprising the following steps:
a. inserting a cleaning gas generator into the interior space of the housing;
b. the cleaning gas generator producing a cleaning gas jet, the cleaning gas jet being oriented such that the cleaning gas jet strikes an optical surface of an EUV mirror of the mask inspection device; and
c. taking the cleaning gas generator out of the interior space of the housing.

2. The method of claim 1, wherein the housing is vacuum-tight.

3. The method of claim 1, wherein the housing is provided with a housing opening and wherein the housing opening is closed by a closure device during operation of the mask inspection device.

4. The method of claim 3, wherein a cleaning head of the cleaning gas generator is inserted through the housing opening into the interior space of the mask inspection device.

5. The method of claim 1, wherein the cleaning gas generator inserted into the interior space terminates vacuum-tightly with the housing.

6. The method of claim 1, wherein the housing opening is an inspection opening which is closed by a housing cover during operation of the mask inspection device.

7. The method of claim 3, wherein the closure device bears an image sensor of the mask inspection device.

8. The method of claim 3, wherein the closure device bears an EUV mirror.

9. The method of claim 1, wherein the cleaning gas jet comprises hydrogen radicals.

10. The method of claim 1, wherein a first EUV mirror of larger surface area is subjected to cleaning and wherein a second EUV mirror of smaller surface area is not subjected to any cleaning.

11. The method of claim 1, wherein the cleaning gas generator is brought into a first state in order to clean a first EUV mirror, and is brought into a second state in order to clean a second EUV mirror.

12. The method of claim 1, wherein a second EUV mirror is separated from the mask inspection device while a first EUV mirror is cleaned.

13. The method of claim 12, wherein the second EUV mirror is cleaned in a cleaning station outside the mask inspection device.

14. A mask inspection system comprising a mask inspection device and a cleaning gas generator for producing a cleaning gas jet, wherein the mask inspection device comprises an image sensor, a housing, and a plurality of EUV mirrors located in the housing, wherein, in a state of use of the mask inspection system, the cleaning gas generator is separated from the mask inspection device and the mask inspection device is configured to receive image data from a photomask by use of the image sensor, and wherein, in a cleaning state, a cleaning gas generator is inserted into an interior space of the mask inspection device such that the cleaning gas jet is directed onto an optical surface of an EUV mirror of the mask inspection device.

15. A cleaning station comprising a chamber intended for receiving an EUV mirror and a generator unit for producing a cleaning gas jet from hydrogen radicals, wherein the generator unit is configured such that the cleaning gas jet strikes the optical surface of the EUV mirror located in the chamber.

16. The mask inspection system of claim 14 wherein the housing is vacuum-tight.

17. The mask inspection system of claim 14 wherein the housing is provided with a housing opening and wherein the housing opening is closed by a closure device during operation of the mask inspection device.

18. The mask inspection system of claim 17 wherein a cleaning head of the cleaning gas generator is inserted through the housing opening into the interior space of the mask inspection device.

19. The mask inspection system of claim 14 wherein the cleaning gas generator inserted into the interior space terminates vacuum-tightly with the housing.

20. The mask inspection system of claim 17 wherein the closure device bears an image sensor of the mask inspection device.
